(19) United States
(12) Patent Application Publication
(10) Pub. No.: US 2026/0314332 A1
(43) Pub. Date: Oct. 8, 2026

(54) FILAMENT FOR HEATER PEDESTAL

(71) Applicant: Lam Research Corporation, Fremont, CA (US)

(72) Inventor: Sairam Sundaram, Wilsonville, OR (US)

(21) Appl. No.: 19/477,004

(22) PCT Filed: Apr. 30, 2024
(86) PCT No.: PCT/US2024/027101

§ 371 Date: Oct. 20, 2025

Related U.S. Application Data
(60) Provisional application No. 63/500,239, filed on May 4, 2023.

(51) Int. Cl. H10P 72/76; H01J 37/32; H10P 72/00

(52) U.S. Cl. CPC H10P 72/7624; H01J 37/32715; H10P 72/0432

(57) ABSTRACT

Various embodiments herein relate to pedestals for semiconductor processing, as well as methods for their use and manufacture. In certain embodiments, a pedestal for supporting a semiconductor substrate during processing includes: a body having an inner portion and an outer portion surrounding the inner portion; an inner filament positioned in the inner portion of the body, the inner filament having a first temperature coefficient of resistance (TCR); and an outer filament positioned in the outer portion of the body, the outer filament having a second TCR, wherein the second TCR is different from the first TCR.

### INCORPORATION BY REFERENCE

A PCT Request Form is filed concurrently with this specification as part of the present application. Each application that the present application claims benefit of or priority to as identified in the concurrently filed PCT Request From is incorporated by reference herein in their entireties and for all purposes.

### FIELD

Various implementations herein relate to filaments for use in a heater pedestal for processing semiconductor substrates, as well as methods and apparatuses that use such filaments.

### BACKGROUND

Semiconductor processing often involves controlling the temperature of a semiconductor substrate that is being processed. One method of controlling the substrate temperature involves placing the substrate on a temperature-controlled pedestal inside a processing chamber. The pedestal is sometimes referred to as a substrate support, chuck, etc.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods and apparatus for processing a semiconductor substrate, as well as methods for fabricating such apparatus. In various embodiments, the method or apparatus includes a pedestal having particular characteristics. For instance, in one aspect of the disclosed embodiments, a pedestal for supporting a semiconductor substrate during processing is provided, the pedestal including: a body having an inner portion and an outer portion surrounding the inner portion; an inner filament positioned in the inner portion of the body, the inner filament having a first temperature coefficient of resistance (TCR); and an outer filament positioned in the outer portion of the body, the outer filament having a second TCR, where the second TCR is different from the first TCR.

In various embodiments, the inner filament and the outer filament may be configured to be powered together by a single power supply. For example, the inner filament and the outer filament may be physically and electrically connected with one another.

The pedestal may include any number of portions, each having a filament therein. For instance, in various embodiments, the body of the pedestal may further include an additional annular portion, the additional annular portion being positioned between the inner portion and the outer portion of the body of the pedestal, the pedestal further including an additional filament positioned in the additional annular portion, where the additional filament has a third TCR, and where the third TCR is different from the first TCR and from the second TCR.

In some embodiments, the second TCR may be greater than the first TCR. In some such embodiments, the second TCR may be greater than the first TCR by at least about 0.1%. In other embodiments, the second TCR may be lower than the first TCR.

A number of materials may be used for the inner filament and the outer filament. In various embodiments, the inner filament and the outer filament may include different materials. In some such embodiments, the inner filament and the outer filament may include different metals. In these or other embodiments, the inner filament and the outer filament may include the same material, but they may be doped with different dopants or doped to different degrees. In various embodiments, the inner filament and/or outer filament may have been subjected to a heat treatment and/or to a plasma treatment to modify the first TCR and/or the second TCR, respectively.

In some embodiments, the body of the pedestal may further include a second outer portion surrounding the outer portion, the pedestal may further include a second outer filament positioned in the second outer portion, where the inner filament and the outer filament are configured to be powered by a first power supply, and where the second outer filament is configured to be powered by a second power supply, such that the inner filament and the outer filament can be powered independently from the second outer filament.

In another aspect of the disclosed embodiments, a method of processing a substrate is provided, the method including: receiving the substrate on a pedestal in a processing chamber, the pedestal including: a body having an inner portion and an outer portion surrounding the inner portion, the body having a top surface that contacts the substrate; an inner filament positioned in the inner portion of the body, the inner filament having a first temperature coefficient of resistance (TCR); an outer filament positioned in the outer portion of the body, the outer filament having a second TCR, where the second TCR is different from the first TCR; powering the pedestal to raise the pedestal to an elevated temperature; and processing the substrate at the elevated temperature.

In various embodiments, the inner filament and the outer filament may be powered together by a single power supply. In these or other embodiments, a temperature profile on the top surface of the body of the pedestal may be substantially uniform at the elevated temperature.

In some embodiments, powering the pedestal to raise the pedestal to the elevated temperature and processing the substrate at the elevated temperature may include (1) at a first time, powering the pedestal to raise the pedestal to a first temperature and processing the substrate at the first temperature, and (2) at a second time, powering the pedestal to raise the pedestal to a second temperature and processing the substrate at the second temperature, where the first temperature and second temperature differ by at least about 50° C., and where a temperature profile on the top surface of the body of the pedestal is substantially uniform at both the first temperature and at the second temperature.

In another aspect of the disclosed embodiments, a method of fabricating a pedestal for supporting a semiconductor substrate during processing is provided, the method including: providing an inner filament having a first temperature coefficient of resistance (TCR); providing an outer filament having a second TCR, where the second TCR is different from the first TCR, and where both the inner filament and outer filament are configured to be powered together by a single power supply; providing a pedestal body; and sealing the inner filament and the outer filament in the pedestal body.

In some embodiments, the second TCR may be greater than the first TCR. In some such embodiments, the second TCR may be greater than the first TCR by at least about 0.1%. In other embodiments, the second TCR may be lower than the first TCR.

These and other aspects are described further below with reference to the drawings.

### BRIEF DESCRIPTION OF THE DRAWINGS

FIGS. 1A and 1B depict a temperature-controlled pedestal for processing semiconductor substrates.

FIGS. 1C and 1D depict temperature profiles that can arise across the face of a pedestal during processing.

FIG. 1E shows an example of resistance vs. temperature for a filament.

FIG. 1F illustrates resistance vs. temperature for a pedestal that is able to provide a uniform temperature over only a small temperature range.

FIGS. 2A and 2B depict a temperature-controlled pedestal for processing semiconductor substrates according to various embodiments.

FIG. 2C is a graph showing resistance vs. temperature for an example pedestal according to the embodiment shown in FIGS. 2A and 2B.

FIG. 2D is a graph showing the temperature profile across the example pedestal according to the example of FIGS. 2A-2C.

FIG. 3 shows an example deposition apparatus according to various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Many semiconductor processing operations can be optimized by controlling the temperature of the substrate being processed. Such operations can include, but are not limited to, deposition, etching, plasma treatments, thermal treatments, etc. The embodiments herein are not limited to any specific kind of semiconductor substrate processing. Rather, the embodiments disclosed herein may apply to many different types of processing.

One technique available for controlling the temperature of a semiconductor substrate during processing is to provide a temperature-controlled pedestal on which the substrate is supported. One purpose of the pedestal is to heat the substrate to a desired processing temperature. Such pedestals can include heating elements and/or cooling elements to control temperature, as desired. In many cases, the heating element includes a filament that is heated via resistive heating. The filament heats the pedestal to an elevated temperature, for example between about 250° C. and about 700° C. in many embodiments. Temperatures outside this range may also be used.

It can be challenging to ensure that all portions of the pedestal that contact the substrate are at a uniform temperature. Without the desired temperature uniformity, the substrate processing results can be poor and non-uniform. For instance, in many cases it is desirable that the substrate temperature vary less than about 5° C. across the entire surface of the substrate. This tight substrate temperature range promotes uniform processing results on the substrate, such as deposition of a film with uniform properties across the face of the substrate. Without appropriate temperature control, the die-to-die variations across the substrate that result from processing at different temperatures can rise to unacceptable levels.

Furthermore, it is especially challenging to design a pedestal that can achieve the desired temperature uniformity at different target processing temperatures. As explained further below, many temperature-controlled pedestals are designed for operating at a single temperature or at a very narrow range of temperatures. When operated outside of these temperatures, the pedestals are often unable to provide an acceptably uniform temperature across the face of the pedestal, resulting in a temperature gradient both on the pedestal and on the substrate being processed. This leads to poor processing results.

The pedestal includes one or more filament surrounded by a body. In some cases, the filament includes a metal, a ceramic metal-based material (e.g., a cermet material), a metallic alloy, a carbon-based material, a graphite-based material, etc. In various embodiments, the filament may include one or more metal selected from the group consisting of molybdenum, tungsten, iron, chrome, aluminum, nickel, platinum, tantalum, rhodium, and combinations thereof. Particular examples for filament materials include, but are not limited to, tungsten, iron-chrome-aluminum, nickel-chrome, molybdenum, tungsten, platinum, tantalum-rhodium, platinum-rhodium, etc.

In many semiconductor processing applications, particularly those using high temperatures, the preferred material for the body of the pedestal is ceramic due to its ability to be heated to high temperatures without material changes that would otherwise compromise functioning of the pedestal. However, ceramic materials have significantly lower thermal conductivity compared to other materials such as metals. As a result, the temperature does not equilibrate well within the ceramic pedestal. Further, due to the geometry of the pedestal, different portions of the pedestal lose heat at different rates, which results in different nominal pedestal temperatures at different locations on the pedestal. Typically, the heat loss is greatest at the outer edge of the pedestal. These heat losses can occur through radiation, convection, and conduction, all of which are temperature dependent.

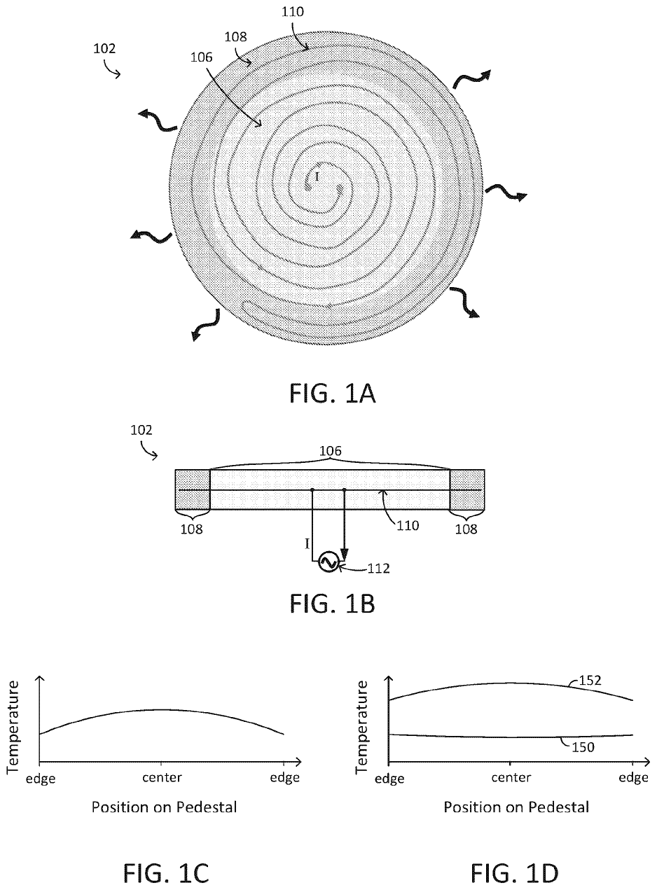

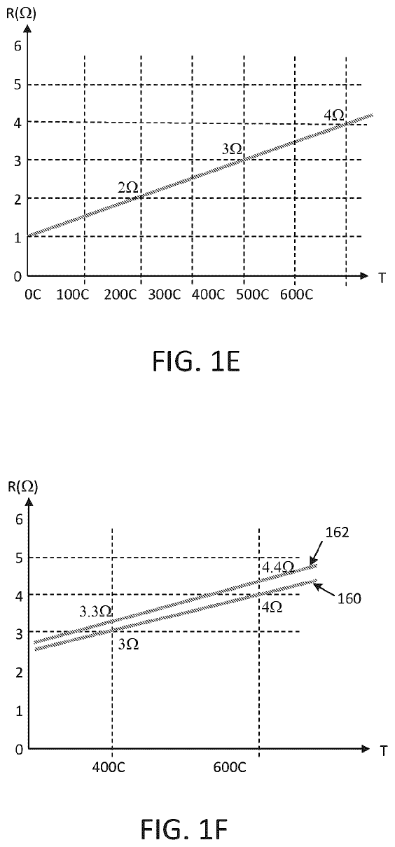

FIGS. 1A and 1B illustrate a pedestal 102 used in semiconductor processing. FIG. 1A shows the pedestal 102 from the top, and FIG. 1B shows the pedestal 102 from the side. The pedestal includes an inner portion 106 and an outer portion 108. The inner portion 106 and outer portion 108 typically form a unitary body, with the outer portion 108 surrounding the inner portion 106. In other words, while the inner portion 106 and the outer portion 108 are labeled as two separate elements, it is understood that these elements refer to different sections of a single pedestal body, as shown in FIGS. 1A and 1B. A filament 110 winds through the pedestal 102, including in both the inner portion 106 and the outer portion 108. The filament is in electrical contact with a power supply 112 that provides power (e.g., current, I) to heat the pedestal 102 via the filament 110.

Without careful design of the filament 110 and its placement within the pedestal 102, heat losses from the outer portion 108 may exceed those from the inner portion 106. As a result, a temperature gradient forms across the pedestal 102, with the highest temperature near the center of the pedestal (e.g., in the inner portion 106) and the lowest temperature near the edge of the pedestal (e.g., in the outer portion 108). This temperature gradient is shown in FIG. 1C.

While FIG. 1C focuses on cases where the pedestal becomes relatively hotter near its center and relatively cooler near its edge, it should be understood that other types of heat gradients can form during processing, as well. For instance, some pedestals may become relatively cooler near their centers and relatively hotter near their edges during processing. Such a heat gradient may arise in certain cases where the body of the pedestal is supported on a stem, where the stem experiences substantial heat loss. The stem of the pedestal supports the body of the pedestal at its center. In cases where heat loss through the stem is substantial, it can cause the body of the pedestal to be relatively cooler near its center (proximate where heat is being lost through the stem) and relatively warmer near its edges. While most of the examples herein are presented in the context of a pedestal that is relatively warmer at its center and cooler at its edges, as shown in FIG. 1C, the techniques herein may be applied to pedestals that would otherwise exhibit any type of temperature gradient. Further, while most of the examples herein are presented in the context of a pedestal that has two portions (e.g., an inner portion and an outer portion), any number of portions can be defined on the pedestal to fine-tune the heating to promote uniform temperature processing.

Various techniques have been developed to combat these temperature gradients. For instance, instead of using a single filament, multiple filaments may be used. The filaments may be positioned in different portions of the pedestal, thereby creating different heating zones on the pedestal. For example, a first filament may be positioned in the inner portion of the pedestal and a second filament may be positioned in the outer portion of the pedestal, thereby creating an inner heating zone and an outer heating zone. Additional filaments/heating zones may be provided as desired. Each filament can be independently powered, thereby allowing the different portions of the pedestal to be heated at different rates and achieving a more uniform temperature across the pedestal. Moreover, the independent heating control for the different heating zones allows a single pedestal to provide the desired temperature uniformity over a relatively wide range of target processing temperatures. Such multi-zone pedestals are quite valuable because a single pedestal can be used for many different processes at different target temperatures. On the other hand, multi-zone pedestals are fairly complicated and expensive to produce. Each additional heating zone introduces substantial cost to the pedestal. Such costs may be associated with processes such as brazing the relevant electrical connections, and/or hardware such as additional power supplies, wiring, etc. It is frequently desirable to keep these costs low to minimize the apparatus costs associated with substrate processing.

Another technique that may be used to combat the temperature gradient across the pedestal is to use a pedestal having a single filament that has been carefully placed to provide a uniform temperature across the pedestal. For instance, the filament may be positioned (e.g., wound) within the pedestal in a manner that provides non-uniform coil density and/or non-uniform filament density. This non-uniform filament placement results in different rates of heating within different portions of the pedestal, thereby balancing the different rates of heat loss from the different portions of the pedestal. Of course, it should be understood that instead of a single filament, multiple filaments can be used instead. Such filaments are electrically connected to one another and are all powered by a single power supply, resulting in a pedestal that is considered to have only a single heating zone. This contrasts with the technique described above where multiple power supplies are provided to independently power filaments to create different independently controllable heating zones on the substrate.

The single heating zone technique is advantageous because it requires only a single filament powered by a single power supply. As such, this technique is relatively more affordable to implement compared to the multiple heating zone approach described above. However, this technique produces pedestals that provide a desired level of temperature uniformity only over a very limited temperature range (e.g., in some cases a range of about 25° C. or less). For instance, a first pedestal may provide an acceptably uniform pedestal temperature over a range between about 250° C. and about 275° C., while a second pedestal having a different filament layout may provide an acceptably uniform pedestal temperature over a range between about 275° C. and about 300° C., etc.

FIG. 1D depicts a graph showing temperature vs. position on the pedestal for a pedestal having a single heating zone. In this example, the pedestal is designed to operate at a temperature of about 400° C. Two different scenarios are depicted. In a first scenario shown by line 150, the pedestal is operated at about 400° C. Because this is the temperature at which the pedestal was designed to operate, the temperature across the face of the pedestal is extremely uniform. In a second scenario shown by line 152, the pedestal is operated at a temperature of about 600° C., about 200° C. above its intended operating temperature. In this case, a temperature gradient forms across the face of the pedestal, with the highest temperature near the center of the pedestal and the lowest temperature near the edges of the pedestal. A substrate processed in the first scenario shown by line 150 will show high quality, uniform results. By contrast, a substrate processed in the second scenario shown by line 152 will show comparatively lower quality, less uniform results due to the temperature gradient that forms on the substrate during processing.

The pedestal described in connection with FIG. 1D is capable of providing a uniform temperature in the first scenario, but not in the second scenario. This is a common problem with pedestals having only a single heating zone. The pedestal is simply unable to accommodate for the larger heat losses near the edges of the pedestal that occur at the higher temperatures of the second scenario.

Various embodiments herein address the issues discussed above by providing a pedestal having a single power supply and multiple filaments, where the filaments have different properties but are all driven by the same power supply. More specifically, the filaments are selected to have different temperature coefficients of resistance (TCR).

Each material has an intrinsic property known as electrical resistivity, which refers to the resistance the material offers to electrical current flow. Electrical resistance is the corresponding extrinsic property and further depends on, e.g., the geometry of the relevant structure and the path of the current flow. This resistance to current flow manifests as heat (e.g., Joule heating) and is the basis for resistive heating.

Electrical resistivity (and therefore electrical resistance) is often highly dependent on temperature. Typically, the resistivity and resistance increase with temperature. This sensitivity of resistivity to temperature is a material property referred to as the TCR. For instance, a typical value of TCR for a material such as molybdenum is approximately 0.005/° C. (with regard to a reference temperature such as 0° C.). This TCR represents the rate at which a 1 Ohm resistance at the reference temperature (e.g., 0° C.) increases in value with temperature.

Previously, where multiple filaments have been driven by a single power supply, the filaments have been uniform with respect to one another (e.g., being made of the same material), and thus have the same TCR. In some other embodiments, the pedestal may have multiple heating zones with multiple power supplies, but at least one of the power supplies powers a heating zone as described herein, e.g., having filaments with different TCRs in different portions of the heating zone driven by the power supply. In other words, although the techniques described herein are particularly useful for fabricating pedestals having only a single heating zone with a single power supply, these techniques are not so limited and can also be used to fabricate pedestals having multiple heating zones and multiple power supplies.

FIG. 1E shows an example of resistance vs. temperature for a molybdenum (or other) filament. In this example, the molybdenum filament has a TCR of about 0.005/° C., and a resistance of about 1 Ohm at the reference temperature of about 0° C. It can be seen that for every 200° C. increase in temperature, the resistance increases by about 1 Ohm (or more generally, by the resistance value at 0° C.). The slope of the line shown in FIG. 1E is the TCR. At 200° C. the resistance is 2 Ohms, at 400° C. the resistance is 3 Ohms, at 600° C. the resistance is 4 Ohms, etc. When a current (e.g., about 10 Amps) is driven through this resistance it produces Joule heating power given by the square of the current times the resistance. Therefore, at 0° C. the resistance would provide 100 W, at 200° C. the resistance would provide 200 W, at 400° C. the resistance would provide 300 W, at 600° C. the resistance would provide 400 W, etc.

As mentioned above, resistivity is an intrinsic material property while resistance is an extrinsic property that depends on geometry. As such, a filament (or collection of filaments) having a uniform TCR can produce different resistances in different portions of the pedestal, depending on the geometry of the filament within the pedestal.

By contrast, in various embodiments herein, a different technique is used. In short, the technique involves selecting filaments having different TCRs in different portions of the pedestal. In many embodiments, the pedestal includes both an inner portion and an outer portion, as described in relation to FIG. 1A, for example. The TCR and resistance of the filament passing through the inner portion of the pedestal can be different from the TCR and resistance of the filament passing through the outer portion of the pedestal. Typically, the filament is arranged such that the resistance of the filament passing through the outer portion is greater than the resistance of the filament passing through the inner portion (the inner and outer portions having about equal surface area) to accommodate for the greater heat losses that occur near the edges of the pedestal compared to the center. Of course, the opposite may be true in cases where it is desired to combat relatively greater heat loss near the inner portion of the pedestal and relatively lower heat loss near the outer portion of the pedestal.

In one example shown in FIG. 1F, it is determined through modeling that 630W of power is desired to maintain the pedestal at a uniform temperature of about 400° C., with 300 W of the power accounting for heat loss through the inner portion of the pedestal and 330 W of the power accounting for heat loss through the outer portion of the pedestal (the inner and outer portions having about equal surface area and being powered together by a single power supply). A resistive molybdenum coil filament is embedded in the pedestal such that the section of the filament in the inner portion of the pedestal (represented by line 160) has a cumulative resistance of about 3 Ohms at about 400° C., and the section of the filament in the outer portion of the pedestal (represented by line 162) has a cumulative resistance of about 3.3 Ohms at about 400° C. Upon running a current of about 10 A through the filament to heat the filament, pedestal, and substrate, the section of filament in the inner portion of the pedestal provides about 300 W of power, and the section of the filament in the outer portion of the pedestal provides about 330 W of power, thus providing a total power of about 630 W, as needed to maintain the pedestal at the desired temperature of about 400° C.

In connection with this same example pedestal operated at a different temperature of about 600° C., it is determined through modeling that 3600 W of power are needed to maintain the pedestal at a uniform temperature, with about 1600 W accounting for heat losses from the inner portion of the pedestal, and about 2000 W accounting for heat losses from the outer portion of the pedestal. As shown in FIG. 1F, at 600° C., the section of the filament in the inner portion of the pedestal (represented by line 160) has a resistance of about 4 Ohms, and the section of the filament in the outer portion of the pedestal (represented by line 162) has a resistance of about 4.4 Ohms. Increasing the heating current to 20 A now provides the inner portion of the pedestal with the desired 1600 W (20 A²*4 Ohms=1600 W); however, the outer portion of the pedestal is only heated at 1760 W (20 A²*4.4 Ohms=1760 W, which is 240 W short of the power needed to maintain the outer portion of the pedestal at the desired temperature of 600° C. As a result, the edges of the pedestal will be cooler than the desired 600° C., and the edge of the substrate being processed will be cooler than its intended processing temperature.

The temperature profiles that are produced across the face of the pedestal can be described with reference to FIG. 1D. For instance, line 150 represents the temperature profile across the face of the pedestal when the pedestal is heated to a temperature of about 400° C., the temperature at which it was designed to operate. In this case, the temperature profile is substantially uniform across the pedestal. By contrast, line 152 represents the temperature profile across the face of the pedestal when the pedestal is heated to a temperature of about 600° C., which is substantially higher than the temperature at which it was designed to operate.

Simply increasing the current provided to the filament cannot solve the problem, because the ratio between power provided to the inner and outer portions of the pedestal does not change. In other words, if the current provided to the filament is increased to provide the desired heating to the outer portion of the pedestal, the inner portion of the pedestal will become too hot, and the center region of the substrate being processed on the pedestal will be similarly above the desired processing temperature.

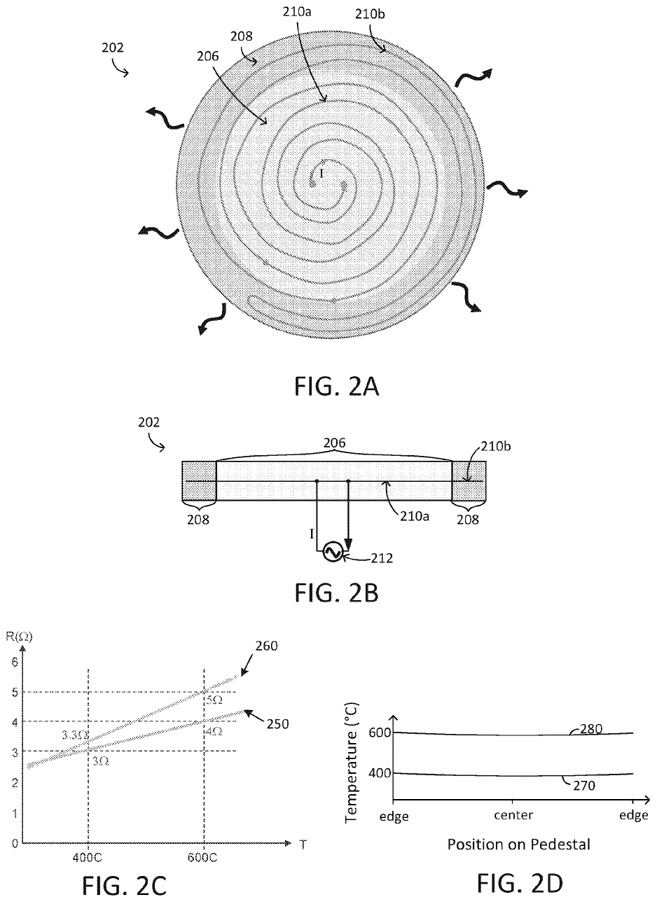

As mentioned above, this issue can be solved by providing filaments having non-uniform TCR on different regions of the pedestal. FIGS. 2A and 2B illustrate an example pedestal 202, with FIG. 2A showing the pedestal 202 from the top, and FIG. 2B showing the pedestal 202 from the side. The pedestal 202 includes an inner portion 206 and an outer portion 208 (additional annular portions can be defined as desired). An inner filament 210a has a first TCR and is positioned within the inner portion 206. An outer filament 210b has a second TCR (which differs from the first TCR) and is positioned within the outer portion 208. Where additional annular portions are defined, they can each have a filament having a particular TCR. The TCRs for the different filaments may differ by a particular degree in some embodiments. For instance, the pedestal may have a second TCR that is greater than (or less than) the first TCR by at least about 0.1%, or at least about 0.5%, or at least about 1%, or at least about 3%, or at least about 5%, or at least about 10%, or at least about 20%, or at least about 30%. Generally, the desired difference in TCR can be selected based on the desired range of operating temperature and the desired degree of sensitivity.

In various embodiments, the inner filament 210a and the outer filament 210b are electrically connected to one another, and are driven by the same power supply 212. In other words, the inner filament 210a and the outer filament 210b are not independently controllable with respect to the current/power provided to them by the power supply. In various embodiments, the inner filament 210a is positioned entirely within the inner portion 206 of the pedestal 202, and the outer filament 210b is positioned entirely within the outer portion 208 of the pedestal, with the inner filament 210a and outer filament 210b being connected with one another at an interface between the inner portion 206 and outer portion 208 of the pedestal 202. In some embodiments, the inner filament 210a and the outer filament 210b may be portions of a single filament. In such cases, the inner filament 210a and/or the outer filament 210b may be subjected to a treatment to modify its TCR, such that the TCR of the inner and outer filaments are different from one another. Of course, either or both of the inner filament 210a and outer filament 210b can be made of a plurality of filaments that are connected with one another.

FIG. 2C shows resistance vs. temperature for both the inner filament 210a and the outer filament 210b of the pedestal shown in FIGS. 2A and 2B. In this example, line 250 relates to the inner filament 210a, while line 260 relates to the outer filament 210b.

In an example described in connection with FIGS. 2A-2D, it is determined through modeling that 630 W of power is needed to maintain the pedestal 202 at a uniform temperature of about 400° C., with 300 W of the power accounting for heat loss through the inner portion 206 of the pedestal and 330 W of the power accounting for heat loss through the outer portion 208 of the pedestal (the inner and outer portions having about equal surface area and being powered together by a single power supply). The inner filament 210a (represented by line 250) is embedded in the inner portion 206 of the pedestal, and has a cumulative resistance of about 3 Ohms at about 400° C. The outer filament 210b (represented by line 260) is embedded in the outer portion 208 of the pedestal, and has a cumulative resistance of about 3.3 Ohms at about 400° C. Upon running a current of about 10 A through the filament to heat the filament, pedestal, and substrate, the inner filament 210a provides about 300 W of power, and outer filament 210b provides about 330 W of power, thus providing a total power of about 630 W, as needed to maintain the pedestal 202 at the desired temperature of about 400° C.

In connection with this same example pedestal 202 operated at a different temperature of about 600° C., it is determined through modeling that 3600 W of power are needed to maintain the pedestal 202 at a uniform temperature, with about 1600 W accounting for heat losses from the inner portion 206 of the pedestal, and about 2000 W accounting for heat losses from the outer portion 208 of the pedestal. As shown in FIG. 2C, at 600° C., the inner filament 210a (represented by line 250) has a resistance of about 4 Ohms, and the outer filament 210b (represented by line 260) has a resistance of about 5 Ohms (this is different from the example in FIG. 1F where the outer filament had a resistance of only 4.4 Ohms at 600° C., since it had the same TCR as the inner filament). Increasing the heating current to 20 A now provides the inner filament 210a (and therefor the inner portion 206 of the pedestal) with the desired 1600 W (20 A²*4 Ohms=1600 W). Similarly, the heating current of 20 A now provides the outer filament 210b (and therefor the outer portion 208 of the pedestal) with the desired 2000 W (20 A²*5 Ohms=2000 W). This provides a total of about 3600 W, which was the power needed to maintain the pedestal 202 at a uniform temperature of about 600° C.

FIG. 2D illustrates the temperature profiles that are produced across the face of the pedestal in the example of FIGS. 2A-2C. For instance, line 270 represents the temperature profile across the face of the pedestal when the pedestal is operated at about 400° C., and line 280 represents the temperature profile across the face of the pedestal when the pedestal is operated at a temperature of about 600° C. At both temperatures, a substantially uniform temperature profile is achieved.

The embodiment in FIGS. 2A-C provides substantial improvement over the example in FIGS. 1A-1F, with the greatest benefit being a substantially larger temperature operating window for a single pedestal having only a single power supply. This large processing window means that the pedestal can be used for a wide variety of applications that occur at substantially different temperatures, while still providing high quality and uniform results across the face of the substrate. Moreover, because only a single power supply is used, the cost of such a pedestal is relatively low compared to other pedestals (e.g., pedestals having multiple heating zones independently controlled by multiple power supplies) that can be operated over a similarly wide range of temperatures.

A number of techniques may be used to ensure that the inner filament and the outer filament have different TCRs. For instance, the inner filament and outer filament may be made of different materials. In some cases, the inner filament and outer filament are made of different metals. In one example, the inner filament is molybdenum and the outer filament is tungsten (or vice versa). Appropriate metallurgical processes may be used to bond the filaments to one another. In some embodiments, the inner filament and outer filament are made of the same metal, but at least one of them is doped with a material that is not substantially present in the other filament. For instance, the inner filament may be molybdenum, and the outer filament may be molybdenum doped with one or more dopants such as carbon, nitrogen, phosphorus, etc. Similarly, the outer filament may be molybdenum, and the inner filament may be molybdenum doped with one or more dopants such as carbon, nitrogen, phosphorus, etc.

In another example, one or both of the inner and outer filaments may be subjected to a treatment (e.g., heat treatment, plasma treatment, etc.) to thereby modify the TCR of the filament being treated. This technique can be used to provide inner and outer filaments made of similar materials having different TCRs. In an example heat treatment, a filament may be exposed to an elevated temperature for a particular duration.

As mentioned, in some cases a plasma treatment may be used to modify the TCR of one or more filaments. Various types of plasma may be used including, but not limited to, capacitively coupled plasma, inductively coupled plasma, transformer coupled plasma, microwave coupled plasma, etc. Various power levels and frequencies may be used as desired for a particular application.

In some embodiments, powder metallurgy techniques may be used to fabricate the filament, or some portion thereof.

Regardless of the techniques used to fabricate the filaments, both the inner and outer filaments (and any additional filaments, if used) are encased and sintered within the body of the pedestal. Therefore, any connections between individual filaments are expected to be durable.

As used herein, the term “substantially uniform” as applied to a temperature profile on a pedestal is intended to mean that the difference between the highest temperature and lowest temperature on the pedestal are different from one another by no more than about 5° C. The temperatures that are considered are those on the top face of the pedestal, e.g., the surface that comes into contact with a substrate during processing.

In some particular embodiments, the highest and lowest temperature on the pedestal may be different from one another by no more than about 1° C., or about 2° C., or about 3° C., or about 4° C. In other embodiments, the temperature variation may be higher, for example the highest and lowest temperature on the pedestal may differ from one another by no more than about 10° C., or about 20° C. In various embodiments, the highest temperature on the pedestal may be greater than the lowest temperature on the pedestal by a maximum degree. For instance, the highest temperature on the pedestal may be a maximum of about 1%, or about 2%, or about 3%, or about 5% higher than the lowest temperature on the pedestal, as calculated in Celsius. As an example, for a pedestal operated at an elevated temperature that provides a maximum temperature of about 600° C. and a minimum temperature of about 580° C. on the face of the pedestal, the highest temperature is considered to be about 3.4% higher than the lowest temperature (e.g., (600−580)/580=0.034).

In various embodiments, the pedestal is able to achieve a desired level of temperature uniformity over a wide range of operating temperatures. For instance, the pedestal may achieve a desired level of temperature uniformity (e.g., as described above) over a range of at least about 50° C., or over a range of at least about 100° C., or over a range of at least about 200° C., or over a range of at least about 300° C., or over a range of at least about 500° C. In one example, a pedestal that provides substantial temperature uniformity at both 400° C. and 600° C. is understood to provide the substantial temperature uniformity over a range of at least about 200° C.

### Apparatus

The pedestal and filaments described herein may be incorporated in any type of semiconductor substrate processing apparatus. As described above, the techniques described herein are useful for many different types of substrate processing, including but not limited to deposition, etching, substrate treatment, etc. In particular, the techniques herein are useful for apparatuses that are operated at different temperatures at different times. The use of filaments with different TCRs in different portions of the pedestal enables the pedestal to achieve a substantially uniform temperature across a wide range of temperatures. This uniformity is achieved without the complications and costs that arise from multi-zone heating with multiple individually controllable power supplies.

For the sake of brevity, only a single example apparatus is described in this section. It should be understood that the concepts disclosed herein can be similarly applied to apparatuses of different kinds.

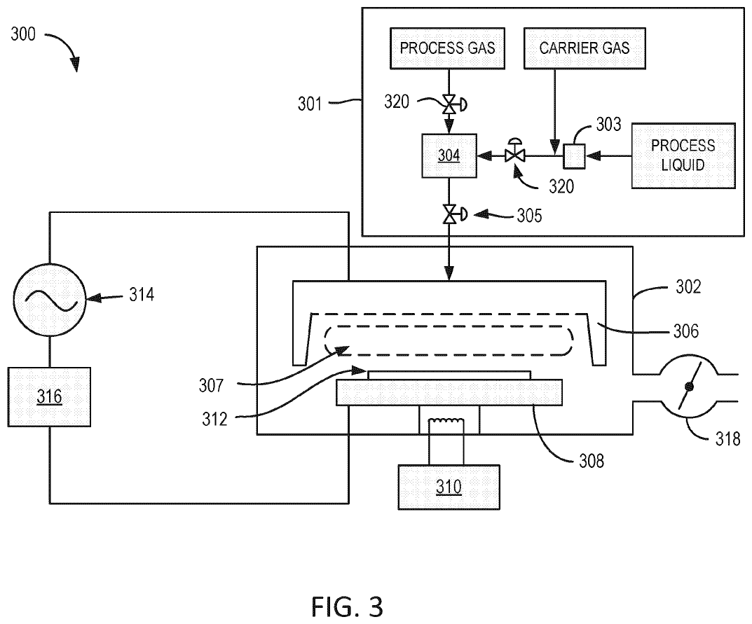

FIG. 3 schematically shows an embodiment of a process station 300 that may be used to deposit material using atomic layer deposition (ALD) and/or chemical vapor deposition (CVD), either of which may be plasma enhanced. For simplicity, the process station 300 is depicted as a standalone process station having a process chamber body 302 for maintaining a low-pressure environment. However, it will be appreciated that a plurality of process stations 300 may be included in a common process tool environment. Further, it will be appreciated that, in some embodiments, one or more hardware parameters of process station 300, including those discussed in detail below, may be adjusted programmatically by one or more computer controllers.

Process station 300 fluidly communicates with reactant delivery system 301 for delivering process gases to a distribution showerhead 306. Reactant delivery system 301 includes a mixing vessel 304 for blending and/or conditioning process gases for delivery to showerhead 306. One or more mixing vessel inlet valves 320 may control introduction of process gases to mixing vessel 304. Similarly, a showerhead inlet valve 305 may control introduction of process gasses to the showerhead 306.

Some reactants may be stored in liquid form prior to vaporization at and subsequent delivery to the process station. For example, the embodiment of FIG. 3 includes a vaporization point 303 for vaporizing liquid reactant to be supplied to mixing vessel 304. In some embodiments, vaporization point 303 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 303 may be heat traced. In some examples, mixing vessel 304 may also be heat traced. In one non-limiting example, piping downstream of vaporization point 303 has an increasing temperature profile extending from approximately 100° C. to approximately 150° C. at mixing vessel 304.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel 304. In another scenario, a liquid injector may be mounted directly to showerhead 306.

In some embodiments, a liquid flow controller upstream of vaporization point 303 may be provided for controlling a mass flow of liquid for vaporization and delivery to process station 300. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 306 distributes process gases toward substrate 312. In the embodiment shown in FIG. 3, substrate 312 is located beneath showerhead 306, and is shown resting on a pedestal 308. It will be appreciated that showerhead 306 may have any suitable shape, and may have any suitable number and arrangement of ports for distributing processes gases to substrate 312. Although the details are not shown in FIG. 3, it is understood that the pedestal 308 may include the features described herein. These features include, but are not limited to, an inner portion housing an inner filament and an outer portion housing an outer filament, where the inner and outer filaments have different TCRs. These features enable the pedestal 308 to be operated at a substantially uniform temperature across a wide range of target operating temperatures. Additional portions and filaments may be provided as desired, as explained above.

In some embodiments, a microvolume 307 is located beneath showerhead 306. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 308 may be raised or lowered to expose substrate 312 to microvolume 307 and/or to vary a volume of microvolume 307. For example, in a substrate transfer phase, pedestal 308 may be lowered to allow substrate 312 to be loaded onto pedestal 308. During a deposition process phase, pedestal 308 may be raised to position substrate 312 within microvolume 307. In some embodiments, microvolume 307 may completely enclose substrate 312 as well as a portion of pedestal 308 to create a region of high flow impedance during a deposition process.

Optionally, pedestal 308 may be lowered and/or raised during portions the deposition process to modulate process pressure, reactant concentration, etc., within microvolume 307. In one scenario where process chamber body 302 remains at a base pressure during the deposition process, lowering pedestal 308 may allow microvolume 307 to be evacuated. Example ratios of microvolume to process chamber volume include, but are not limited to, volume ratios between 1:300 and 1:10. It will be appreciated that, in some embodiments, pedestal height may be adjusted programmatically by a suitable computer controller.

In another scenario, adjusting a height of pedestal 308 may allow a plasma density to be varied during plasma activation and/or treatment cycles included in the deposition process. At the conclusion of the deposition process phase, pedestal 308 may be lowered during another substrate transfer phase to allow removal of substrate 312 from pedestal 308.

While the example microvolume variations described herein refer to a height-adjustable pedestal, it will be appreciated that, in some embodiments, a position of showerhead 306 may be adjusted relative to pedestal 308 to vary a volume of microvolume 307. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers.

Returning to the embodiment shown in FIG. 3, showerhead 306 and pedestal 308 electrically communicate with RF power supply 314 and matching network 316 for powering a plasma. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are included above. Likewise, RF power supply 314 may provide RF power of any suitable frequency. In some embodiments, RF power supply 314 may be configured to control high-and low-frequency RF power sources independently of one another. Example low-frequency RF frequencies may include, but are not limited to, frequencies between 50 kHz and 300 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 308 may be temperature controlled via heater 310 (analogous to power supply 212 of FIG. 2B). Further, in some embodiments, pressure control for deposition process station 300 may be provided by butterfly valve 318. As shown in the embodiment of FIG. 3, butterfly valve 318 throttles a vacuum provided by a downstream vacuum pump (not shown). However, in some embodiments, pressure control of process station 300 may also be adjusted by varying a flow rate of one or more gases introduced to process station 300.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As used herein, the term “about” as applied to a numerical value is understood to mean±10% of the relevant value.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A pedestal for supporting a semiconductor substrate during processing, the pedestal comprising:
a body having an inner portion and an outer portion surrounding the inner portion;
an inner filament positioned in the inner portion of the body, the inner filament having a first temperature coefficient of resistance (TCR); and
an outer filament positioned in the outer portion of the body, the outer filament having a second TCR, wherein the second TCR is different from the first TCR.

2. The pedestal of claim 1, wherein the inner filament and the outer filament are configured to be powered together by a single power supply.

3. The pedestal of claim 1, wherein the body of the pedestal further comprises an additional annular portion, the additional annular portion being positioned between the inner portion and the outer portion of the body of the pedestal, the pedestal further comprising an additional filament positioned in the additional annular portion, wherein the additional filament has a third TCR, and wherein the third TCR is different from the first TCR and from the second TCR.

4. The pedestal of claim 1, wherein the second TCR is greater than the first TCR.

5. The pedestal of claim 4, wherein the second TCR is greater than the first TCR by at least about 0.1%.

6. The pedestal of claim 1, wherein the second TCR is lower than the first TCR.

7. The pedestal of claim 1, wherein the inner filament and the outer filament comprise different materials.

8. The pedestal of claim 7, wherein the inner filament and the outer filament comprise different metals.

9. The pedestal of claim 1, wherein the inner filament and the outer filament comprise the same material, but doped with different dopants or doped to different degrees.

10. The pedestal of claim 7, wherein the inner filament and/or outer filament have been subjected to a heat treatment and/or to a plasma treatment to modify the first TCR and/or the second TCR, respectively.

11. The pedestal of claim 1, wherein the body of the pedestal further comprises a second outer portion surrounding the outer portion, the pedestal further comprising a second outer filament positioned in the second outer portion, wherein the inner filament and the outer filament are configured to be powered by a first power supply, and wherein the second outer filament is configured to be powered by a second power supply, such that the inner filament and the outer filament can be powered independently from the second outer filament.

12. A method of processing a substrate, the method comprising:
receiving the substrate on a pedestal in a processing chamber, the pedestal comprising:
a body having an inner portion and an outer portion surrounding the inner portion, the body having a top surface that contacts the substrate;
an inner filament positioned in the inner portion of the body, the inner filament having a first temperature coefficient of resistance (TCR);
an outer filament positioned in the outer portion of the body, the outer filament having a second TCR, wherein the second TCR is different from the first TCR;
powering the pedestal to raise the pedestal to an elevated temperature; and
processing the substrate at the elevated temperature.

13. The method of claim 12, wherein the inner filament and the outer filament are powered together by a single power supply.

14. The method of claim 12, wherein a temperature profile on the top surface of the body of the pedestal is substantially uniform at the elevated temperature.

15. The method of claim 12, wherein powering the pedestal to raise the pedestal to the elevated temperature and processing the substrate at the elevated temperature comprises (1) at a first time, powering the pedestal to raise the pedestal to a first temperature and processing the substrate at the first temperature, and (2) at a second time, powering the pedestal to raise the pedestal to a second temperature and processing the substrate at the second temperature, wherein the first temperature and second temperature differ by at least about 50° C., and wherein a temperature profile on the top surface of the body of the pedestal is substantially uniform at both the first temperature and at the second temperature.

16. A method of fabricating a pedestal for supporting a semiconductor substrate during processing, the method comprising:
providing an inner filament having a first temperature coefficient of resistance (TCR);
providing an outer filament having a second TCR, wherein the second TCR is different from the first TCR, and wherein both the inner filament and outer filament are configured to be powered together by a single power supply;
providing a pedestal body; and
sealing the inner filament and the outer filament in the pedestal body.

17. The method of claim 16, wherein the second TCR is greater than the first TCR.

18. The method of claim 17, wherein the second TCR is greater than the first TCR by at least about 0.1%.

19. The method of claim 16, wherein the second TCR is lower than the first TCR.
